(19) United States
(12) Patent Application Publication
(10) Pub. No.: US 2013/0330531 A1
(43) Pub. Date: Dec. 12, 2013

(54) BARRIER STACKS AND METHODS OF MAKING THE SAME

(71) Applicant: CHEIL INDUSTRIES, INC., Uiwang-si (KR)

(72) Inventors: Lorenza Moro, San Carlos, CA (US); Damien Boesch, San Jose, CA (US); Xianghui Zeng, Albany, CA (US); Sina Maghsoodi, San Jose, CA (US)

(73) Assignee: CHEIL INDUSTRIES, INC., Uiwang-si (KR)

(21) Appl. No.: 13/839,584

(22) Filed: Mar. 15, 2013

Related U.S. Application Data
(60) Provisional application No. 61/656,490, filed on Jun. 6, 2012.

(51) Int. Cl. H01L 51/52; C23C 14/34

(52) U.S. Cl. CPC H01L 51/5237; C23C 14/3485
USPC 428/218; 204/192.15; 428/212

(57) ABSTRACT

A barrier stack for protecting devices from the permeation of moisture and gases includes a first layer acting as a planarization, decoupling, and/or smoothing layer, a second layer acting as a plasma resistant protective layer over the first layer, and a third layer acting as a barrier layer over the second layer. The first layer includes a polymeric or organic material. The second layer includes an inorganic material or polymeric material. The third layer includes an inorganic material and has a different density and/or refractive index than the second layer. The barrier stack may further include a fourth layer acting as a tie layer between the first layer and the substrate.

### CROSS-REFERENCE TO RELATED APPLICATION(S)

This application claims priority to and the benefit of U.S. Provisional Application No. 61/656,490, filed Jun. 6, 2012, entitled BARRIER STACKS AND METHODS OF MAKING THE SAME, the entire content of which is incorporated herein by reference.

### TECHNICAL FIELD

The present disclosure is related to barrier stacks for protecting devices from the permeation of moisture and gases, to devices encapsulated by the barrier stacks, and to methods of making the barrier stacks.

### BACKGROUND

Many devices, such as organic light emitting devices and the like, are susceptible to degradation from the permeation of certain liquids and gases, such as water vapor and oxygen present in the environment, and other chemicals that may be used during the manufacture, handling or storage of the product. To reduce permeability to these damaging liquids, gases and chemicals, the devices are typically coated with a barrier coating or are encapsulated by incorporating a barrier stack adjacent one or both sides of the device.

Barrier coatings typically include a single layer of inorganic material, such as aluminum, silicon or aluminum oxides, or silicon nitrides. However, for many devices, such a single layer barrier coating does not sufficiently reduce or prevent oxygen or water vapor permeability. Indeed, in organic light emitting devices, for example, which require exceedingly low oxygen and water vapor transmission rates, these single layer barrier coatings do not adequately reduce or prevent the permeability of damaging gases, liquids and chemicals. Accordingly, in those devices (e.g., organic light emitting devices and the like), barrier stacks have been used in an effort to further reduce or prevent the permeation of damaging gases, liquids and chemicals.

In general, a barrier stack includes at least one barrier layer and at least one decoupling layer, and can be deposited directly on the device to be protected, or may be deposited on a separate film or support, and then laminated onto the device. The decoupling layer(s) and barrier layer(s) can be deposited by any of various techniques (e.g., vacuum deposition processes or atmospheric processes), but the deposition of suitably dense layers with appropriate barrier properties is typically achieved by supplying energy to the material that will ultimately form the layer. The energy supplied to the material can be thermal energy, but in many deposition processes, ionization radiation is used to increase the ion production in the plasma and/or to increase the number of ions in the evaporated material streams. The produced ions are then accelerated toward the substrate either by applying a DC or AC bias to the substrate, or by building up a potential difference between the plasma and the substrate.

For example, low energy plasma can be used to deposit the oxides of a barrier layer. However, a layer deposited using such low energy plasma has surface defects and low density, providing limited protection of the encapsulated device (e.g., an organic light emitting device) from the permeation of damaging gases, liquids, and chemicals. A common solution to this problem has been to provide multiple stacks of the decoupling and barrier layers in order to provide an effective barrier stack (or ultrabarrier). However, such a practice increases the cost and time of manufacture.

Additionally, the plasma used to deposit the barrier and/or decoupling layers can damage the devices the barrier stacks are intended to protect. In particular, certain devices, such as organic light emitting devices, are sensitive to plasma, and can be damaged when a plasma based or plasma assisted deposition process is used to deposit the layers of the barrier stack. Damage caused by the plasma based or plasma assisted deposition of the layers of the barrier stack have a negative impact on the electrical and/or luminescent properties of the protected (or encapsulated) device. The type and extent of damage caused by the plasma based or plasma assisted deposition process may vary depending on the type of device, and even on the manufacturer of the device, with some devices registering significant damage and others registering little or no damage. However, some typical effects of plasma damage on organic light emitting devices include higher voltage requirements for achieving the same level of luminescence, reduced luminescence, and undesirable modifications to the properties of certain polymers.

While an ideal solution to the effects of plasma damage may be to cease using plasma in the deposition of the layers of the barrier stacks, such a solution is not always practical or possible. For example, while alternative, less energetic deposition processes (such as RF sputtering, atomic layer deposition, and chemical vapor deposition) have been proposed for different purposes, these techniques are slow, expensive (due to the high vacuum requirement), and impractical. Accordingly, recent efforts have focused on the manufacture of a barrier stack that protects the encapsulated device from the effects of plasma damage caused by the deposition processes. For example, a barrier stack including a composite inorganic barrier layer has been proposed in which the composite layer includes a first oxide layer deposited under high pressure conditions, and a second oxide layer deposited under lower pressure conditions. The high pressure oxide layer does not function as a barrier layer, as the high pressure oxide layer does not have substantial barrier properties due to its considerably less dense, nanoporous structure. Rather, the high pressure oxide layer is intended to prevent the more energetic (lower pressure) plasma deposition process from damaging the underlying polymeric decoupling layer. However, when the low pressure layer is subsequently deposited on the high pressure layer, the porous structure in the high pressure layer leads to defects in the low pressure layer. These defects are caused because the deposition technique is directional rather than conformal. As such, any imperfections in the first (high pressure) layer will lead to similar imperfections in the second (low pressure) layer which cannot be healed by sputtering. To address this issue, the high pressure layer must be both thin enough to avoid the propagation of surface defects to the subsequently deposited low pressure layer, and thick enough to adequately protect the underlying decoupling layer. Achieving the correct thickness of the high pressure layer to achieve these competing goals can be very difficult. Also, the high pressure deposition process is slow and has low throughput.

Plasma resistant polymer formulations have also been proposed as a means for reducing or preventing plasma damage. However, polymer layers that are both plasma resistant and meet all the requirements of a layer of a barrier stack are very difficult, if not impossible, to design.

### SUMMARY

The present invention provides a barrier stack for protecting devices from the permeation of moisture and gases which includes a substrate, a first layer of a planarization, decoupling, and/or smoothing layer over the substrate, a second layer of a plasma resistant protective layer over the first layer, and a third layer of a barrier layer over the second layer. The first layer comprises a polymeric or organic material, the second layer comprises an inorganic material or polymeric material, the third layer comprises an inorganic material, and the third layer has different density and/or refractive index than the second layer.

In one embodiment of the invention, the inorganic material for forming the second layer and/or the third layer is selected from the group consisting of metals, metal oxides, metal nitrides, metal oxynitrides, metal carbides, metal oxyborides, Al, Zr, Ti, and combinations thereof. In another embodiment of the invention, the second layer is formed from a plasma resistant polymeric material.

In one embodiment of the invention, the barrier stack further comprises a fourth layer of a tie layer between the first layer and the substrate.

The method of forming such barrier stacks includes providing a substrate, forming a first layer of a planarization, decoupling, and/or smoothing layer over the substrate, forming a second layer of a protective layer over the first layer, and forming a third layer of a barrier layer over the second layer. In one embodiment of the invention, the second layer is an inorganic material and is formed using pulsed DC sputtering.

### BRIEF DESCRIPTION OF THE DRAWINGS

These and other features and advantages of the present invention will be better understood by reference to the following detailed description when considered in conjunction with the following drawings, in which:

FIG. 1 is a schematic view of a barrier stack according to an embodiment of the present invention;

FIG. 2 is a schematic view of a barrier stack according to another embodiment of the present invention; and

FIG. 3 is a schematic view of a barrier stack according to yet another embodiment of the present invention.

### DETAILED DESCRIPTION

In embodiments of the present invention, a barrier stack includes a plasma resistant protective layer between the decoupling (or smoothing/planarization) layer and the oxide barrier layer. The plasma resistant protective layer enables the use of aggressive (i.e., high power, high voltage, low pressure) plasma conditions for the deposition of the oxide barrier layer. These aggressive plasma conditions yield high quality, dense inorganic layers with good barrier performance. Additionally, the plasma resistant protective layer enables deposition of the barrier layer at high deposition rates, leading to processes with high throughput and productivity as well as wider process windows.

In some embodiments of the present invention, a barrier stack includes first, second and third layers. The layers of the barrier stack can be directly deposited on a device to be encapsulated (or protected) by the barrier stack, or may be deposited on a separate substrate or support, and then laminated on the device. The first layer of the barrier stack includes a polymer or other organic material that serves as a planarization, decoupling and/or smoothing layer. Specifically, the first layer decreases surface roughness, and encapsulates surface defects, such as pits, scratches, digs and particles, thereby creating a planarized surface that is ideal for the subsequent deposition of additional layers. As used herein, the terms “first layer,” “smoothing layer,” “decoupling layer,” and “planarization layer” are used interchangeably, and all terms refer to the first layer, as now defined. The first layer can be deposited directly on the device to be encapsulated (e.g., an organic light emitting device), or may be deposited on a separate support. The first layer may be deposited on the device or substrate by any suitable deposition technique, some nonlimiting examples of which include vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The first layer can include any suitable material capable of acting as a planarization, decoupling and/or smoothing layer. Some nonlimiting examples of suitable such materials include organic polymers, inorganic polymers, organometallic polymers, hybrid organic/inorganic polymer systems, and silicates. In some embodiments, for example, the material of the first layer may be an acrylate-containing polymer, an alkylacrylate-containing polymer (including but not limited to methacrylate-containing polymers), or a silicon-based polymer.

The first layer can have any suitable thickness such that the layer has a substantially planar and/or smooth layer surface. As used herein, the term “substantially” is used as a term of approximation and not as a term of degree, and is intended to account for normal variations and deviations in the measurement or assessment of the planar or smooth characteristic of the first layer. In some embodiments, for example, the first layer has a thickness of about 100 to 1000 nm.

The second layer of the barrier stack includes an inorganic or polymeric material, and serves as a protective layer, shielding the first layer and the underlying encapsulated device from plasma damage caused by the deposition of the third layer, which is discussed in more detail below. The second layer is deposited on the first layer and under the third layer, so that the second layer is between the first and third layers. Deposition of the second layer may vary depending on the material used for the second layer. For example, when the material of the second layer is an inorganic material (e.g., an oxide), the layer may be deposited by pulsed DC sputtering, and when the material of the second layer is a polymeric material, the layer may be deposited by a wet coating method.

For layers deposited by pulsed DC sputtering, the sputtering conditions may vary depending on the material being deposited, and on the gas used to effect the sputtering. Those of ordinary skill in the art would be able to determine the proper sputtering conditions and select an appropriate gas for the sputtering in order to achieve a suitable second layer. Specifically, in order to adequately protect the underlying first layer and encapsulated device, the second layer should have an appropriate thickness, density and refractive index. As is known to those of ordinary skill in the art, thickness is dependent on density, and density is related to refractive index. See, e.g., Smith, et al., “Void formation during film growth: A molecular dynamics simulation study,” J. Appl. Phys., 79 (3), pgs. 1448-1457 (1996); Fabes, et al., “Porosity and composition effects in sol-gel derived interference filters,” Thin Solid Films, 254 (1995), pgs. 175-180; Jerman, et al., “Refractive index of this films of SiO2, ZrO2, and HfO2 as a function of the films' mass density,” Applied Optics, vol. 44, no. 15, pgs. 3006-3012 (2005); Mergel, et al., “Density and refractive index of TiO2 films prepared by reactive evaporation,” Thin Solid Films, 3171 (2000) 218-224; and Mergel, D., “Modeling TiO2 films of various densities as an effective optical medium,” Thin Solid Films, 397 (2001) 216-222, all of which are incorporated herein by reference. Also, the correlation between film density and barrier properties is described, e.g., in Yamada, et al., “The Properties of a New Transparent and Colorless Barrier Film,” Society of Vacuum Coaters, 505/856-7188, 38^{th} Annual Technical Conference Proceedings (1995) ISSN 0737-5921, the entire content of which is also incorporated herein by reference. However, while the density of the harrier film may affect the barrier properties of that film, this reference does not appear to discuss the density of an underlying protective layer and its effect on the protection of the decoupling layer or encapsulated device from plasma damage. Although the second layer (when including an inorganic material) is described as being deposited by pulsed DC sputtering, it is understood that any deposition technique that can deposit a second layer having the appropriate density/refractive index can be used. Such a second layer should have a density/refractive index that is sufficient to prevent or substantially reduce damage to the underlying first layer and encapsulated device without creating (or substantially preventing) the creation of surface defects that will propagate to the later deposited third (barrier) layer. To that end, in some embodiments of the present invention, the refractive index of the second layer may be greater than about 1.6 or lower than about 1.5. As would be understood by those of ordinary skill in the art, the refractive index (and therefore, density) of the second layer will depend on the deposited material, e.g., the atomic number of the metal in the metal oxide. For example, layers including certain oxides (such as, for example aluminum oxide, i.e., Al₂O₃) may have a refractive index of about 1.6 to about 1.7, while layers of other oxides (such as, for example, silicon oxide, i.e., SiO₂) may have a refractive index of about 1.3 to about 1.5. As discussed above, refractive index and density are related, and those of ordinary skill in the art would understand how to calculate film density from these refractive indices. See, e.g., Smith, et al., “Void formation during film growth: A molecular dynamics simulation study,” J. Appl. Phys., 79 (3), pgs. 1448-1457 (1996); Fabes, et al., “Porosity and composition effects in sol-gel derived interference filters,” Thin Solid Films, 254 (1995), pgs. 175-180; Jerman, et al., “Refractive index of this films of SiO2, ZrO2, and HfO2 as a function of the films' mass density,” Applied Optics, vol. 44, no. 15, pgs. 3006-3012 (2005); Mergel, et al., “Density and refractive index of TiO2 films prepared by reactive evaporation,” Thin Solid Films, 3171 (2000) 218-224; and Mergel, D., “Modeling TiO2 films of various densities as an effective optical medium,” Thin Solid Films, 397 (2001) 216-222, previously incorporated herein by reference.

The density/refractive index of the deposited second layer is also related to the thickness of the layer, which can be any thickness capable of yielding a layer having the above described refractive index and/or density. In some embodiments, however, the thickness of the second layer is about 20 nm to about 100 nm, for example, about 20 to about 50 nm, or about 20 to about 40 nm. In some exemplary embodiments, for example, the thickness of the second layer is about 30 nm or about 40 nm. Indeed, the barrier stacks according to embodiments of the present invention can include second (protective) layers that are thicker due to the substantial absence of defect propagation to the third (or barrier) layer. Specifically, the pulsed DC sputtering technique (or other suitable technique) used to deposit the second layer deposits a layer with a refractive index and density that substantially prevents or avoids surface defects which (if present) would propagate to the third (barrier) layer. As is known to those of ordinary skill in the art, layers with densities that are too low have surface defects that propagate to any subsequently deposited layer. As a result, layers with low density are typically made rather thin in an effort to avoid to such surface defects. However, even thin layers contain defects such as nanoscale pores, which is a significant problem for the high pressure layer/low pressure layer barrier discussed above. Also, such thin layers often do not provide sufficient protection of the underlying layers and encapsulated devices from plasma damage caused by the subsequent deposition of additional layers. According to embodiments of the present invention, the deposition technique substantially avoids surface defects in the second layer, enabling the creation of much thicker second layers. These thicker layers provide added protection of the underlying first layers and encapsulated devices without substantially affecting the properties of the encapsulated devices.

The pulsed DC sputtering conditions for depositing the second layer are not particularly limited so long as the conditions are suitable for generating a second layer having the properties described above (e.g., the appropriate refractive index, density and thickness). Indeed, as would be understood by those of ordinary' skill in the art, the pulsed DC sputtering conditions will generally vary depending on the size of the target and the distance between the target and the substrate. Also, those of ordinary skill in the art would be able to devise pulsed DC sputtering conditions suitable to generate a second layer having the desired properties (e.g., the above described refractive index, density and thickness). In some exemplary embodiments, however, the DC sputtering conditions can include a power of about 2 to about 6 kW, for example about 3.2 to about 4.8 kW, a pressure of about 1 to about 5 mTorr, for example about 2.5 mTorr, a target voltage of about 150 to about 400 V, for example about 290V, a gas flow rate of about 50 to about 80 sccm, for example about 65 sccm, and a track speed of about 50 to about 80 cm/min, for example about 64 cm/min. Also, although the inert gas used in the pulsed DC sputtering process can be any suitable inert gas (such as helium, xenon, krypton, etc.), in some embodiments, the inert gas is argon (Ar).

The material of the second layer is not particularly limited, and may be any material suitable for protecting the underlying first layer and encapsulated device from plasma damage. Indeed, the material of the second layer may be the same as the material of the third layer (described below), or may be a different material. Some nonlimiting examples of suitable materials for the second layer include metals, metal oxides, metal nitrides, metal oxynitrides, metal carbides, metal oxyborides, and combinations thereof Those of ordinary skill in the art would be capable of selecting a suitable metal for use in the oxides, nitrides and oxynitrides based on the desired optical properties of the layer. However, in some embodiments, for example, the metal may be Al, Zr or Ti. Si based materials (i.e., silicon oxides, nitrides or oxynitrides) may also be used, but may not be preferable. In addition to metal materials, semiconductor materials may also be used as the material of the second layer, but semiconductor materials may not be preferable.

When the second layer is an organic material, e.g., a polymeric material, the second layer may include any suitable polymeric material capable of substantially shielding the underlying first layer and encapsulated device from plasma damage caused by the subsequent deposition of the third (barrier) layer. For example, the organic material of the second layer may be a polymeric material that is plasma-resistant. Some examples of such plasma-resistant polymer are disclosed in U.S. Pat. No. 7,767,498 to Moro, et al., issued on Aug. 3, 2010, the entire content of which is incorporated herein by reference. In some exemplary embodiments, the organic material of the second layer may be a silicone-based polymer or a carbon-based polymer. Some nonlimiting examples of suitable silicone-based and carbon-based polymers for the second layer include silicones, polybutadienes, styrene butadienes, and the like.

As discussed above, the second layer can be either an inorganic layer or an organic layer. One advantage to the use of an inorganic layer is that the layer also functions as an effective barrier against gases, liquids and chemicals, and therefore contributes to the overall barrier performance of the barrier stack. Another advantage of an inorganic protective (second) layer is that the layer (e.g., oxide layer) is deposited by high energy plasma, yielding a high deposition rate, high throughput and productivity, as well as wider process windows. These advantages yield a second (protective) layer of high quality since it is grown on the surface of a dense amorphous film.

On the other hand, organic second (protective) layers have the advantage of being capable of deposition by wet deposition methods, which methods are fast and reduce production cost (because vacuum is not required). Additionally, organic protective layers may enhance adhesion of the other layers to the first (polymeric decoupling/smoothing/planarization) layers. Also, because organic protective layers are wet deposited as liquids, the surfaces created by these layers are very smooth, and therefore capable of covering any surface defects in the underlying first layer. In addition, the organic material of the layer can be further functionalized to introduce other desirable properties (e.g., UV protection), thereby opening up a wide range of polymers useful as the material of the second layer.

The third layer of the barrier stack is the layer that operates as the barrier layer, preventing the permeation of damaging gases, liquids and chemicals to the encapsulated device. Indeed, as used herein, the terms “third layer” and “barrier layer” are used interchangeably. The third layer is deposited on the second layer, and deposition of the third layer may vary depending on the material used for the third layer. However, in general, any deposition technique and any deposition conditions can be used to deposit the third layer so long as the third layer is deposited in such a manner as to yield a different density and/or refractive index than the second layer. For example, the third layer may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof.

In some embodiments, however, the third layer is deposited by AC sputtering. The AC sputtering deposition technique offers the advantages of faster deposition, better layer properties, process stability, control, fewer particles and fewer arcs. The conditions of the AC sputtering deposition are not particularly limited, and as would be understood by those of ordinary skill in the art, the conditions will vary depending on the area of the target and the distance between the target and the substrate. In some exemplary embodiments, however, the AC sputtering conditions may include a power of about 3 to about 6 kW, for example about 4 kW, a pressure of about 2 to about 6 mTorr, for example about 4.4 mTorr, an Ar flow rate of about 80 to about 120 sccm, for example about 100 sccm, a target voltage of about 350 to about 550 V, for example about 480V, and a track speed of about 90 to about 200 cm·min, for example about 141 cm/min. Also, although the inert gas used in the AC sputtering process can be any suitable inert gas (such as helium, xenon, krypton, etc.), in some embodiments, the inert gas is argon (Ar).

The material of the third layer is not particularly limited, and may be any material suitable for substantially preventing or reducing the permeation of damaging gases, liquids and chemicals (e.g., oxygen and water vapor) to the encapsulated device. Indeed, the material of the third layer may be the same as the material of the second layer (described above), or may be a different material. Some nonlimiting examples of suitable materials for the third layer include metals, metal oxides, metal nitrides, metal oxynitrides, metal carbides, metal oxyborides, and combinations thereof. Those of ordinary skill in the art would be capable of selecting a suitable metal for use in the oxides, nitrides and oxynitrides based on the desired properties of the layer. However, in some embodiments, for example, the metal may be Al, Zr, Si or Ti. While Si based materials (i.e., silicon oxides, nitrides or oxynitrides) may be used in both the second and third layers, such materials may not be particularly preferable for use in the second layer (as noted above).

Also, while the third layer may include the same material as the second layer, the third layer may have a different density and/or refractive index and/or thickness than the second layer due to the different techniques (e.g., pulsed DC sputtering vs. AC sputtering) used to deposit the layers. For example, in some embodiments, the density of the second layer is greater than the density of the third layer. However, the present invention is not limited to this circumstance, and in other exemplary embodiments, the density of the second layer may be lower than the density of the third layer. While the density and refractive index of the third layer is not particularly limited and will vary depending on the material of the layer, in some exemplary embodiments, the third layer has a refractive index of about 1.6 or greater, e.g., 1.675. As discussed above, those of ordinary skill in the art would be able to calculate the density of the layer from the refractive index information. The thickness of the third layer is also not particularly limited. However, in some exemplary embodiments, the thickness is about 20 nm to about 100 nm, for example about 40 nm to about 70 nm, In some embodiments, for example, the thickness of the third layer is about 40 nm.

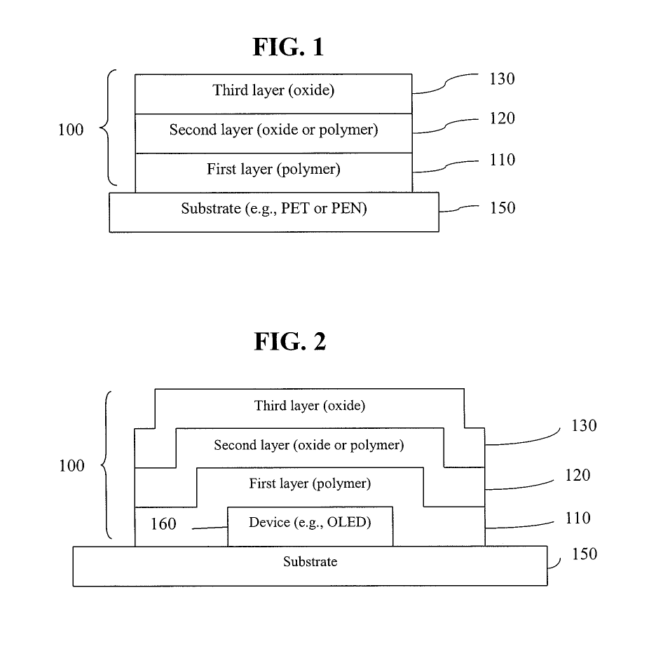

Exemplary embodiments of a barrier stack according to the present invention are illustrated in FIGS. 1 and 2. The barrier stack 100 depicted in FIG. 1 includes a first layer 110 which includes a polymer, a second layer 120 which includes an oxide or silicone protective layer, and a third layer 130 which includes an oxide barrier layer. In FIG. 1, the barrier stack 100 is deposited on a substrate 150, for example glass. However, in FIG. 2, the barrier stack 100 is deposited directly on the device 160, e.g., an organic light emitting device.

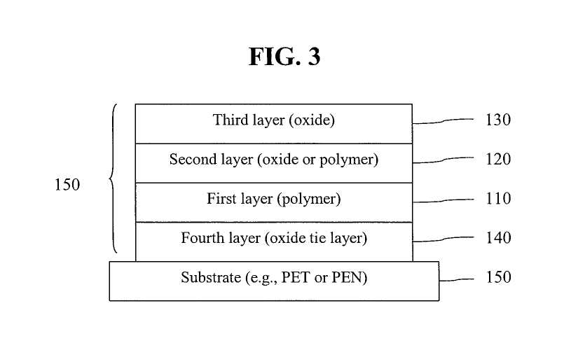

In addition to the first, second and third layers, 110, 120 and 130 respectively, some exemplary embodiments of the barrier stack 100 can include a fourth layer 140 between the first layer 110 and the substrate 150 or the device 160 to be encapsulated. Although the inventive barrier stacks are discussed herein and depicted in the accompanying drawings as including first, second, third and fourth layers 110, 120, 130 and 140 respectively, it is understood that these layers may be deposited on the substrate 150 or the device 160 in any order, and the identification of the layers as a first layer, second layer, third layer, or fourth layer does not mean that the layers must be deposited in that order. Indeed, as discussed here, and depicted in FIG. 3, the fourth layer 140 is deposited on the substrate 150 or device 140 prior to deposition of the first layer 110.

The fourth layer 140 acts as a tie layer, improving adhesion between the layers of the barrier stack 100 and the substrate 150 or the device 160 to be encapsulated. The material of the fourth layer 140 is not particularly limited, and can include the materials described above with respect to the second and third layer. Also, the material of the fourth layer may be the same as or different from the material of either the second layer or the third layer. The materials of the second and third layers are described in detail above.

Additionally, the fourth layer may be deposited on the substrate or the device to be encapsulated by any suitable technique, including, but not limited to the techniques described above with respect to the second and third layers. In some embodiments, for example, the fourth layer may be deposited by AC sputtering under conditions similar to those described above for the third layer. Also, the thickness of the deposited fourth layer is not particularly limited, and can be any thickness suitable to effect good adhesion between the first layer of the barrier stack and the substrate or device to be encapsulated. In some embodiments, for example, the fourth (tie) layer can have a thickness of about 20 nm to about 60 nm, for example, about 40 nm.

An exemplary embodiment of a barrier stack 100 according to the present invention including a fourth layer 140 is depicted in FIG. 3. The barrier stack 100 depicted in FIG. 3 includes a first layer 110 which includes a polymer, a fourth layer 140 which includes an oxide tie layer, a second layer 120 which includes an oxide or silicone protective layer, and a third layer 130 which includes an oxide barrier layer. In FIG. 3, the barrier stack 100 is deposited on a substrate 150, for example glass. However, it is understood that the barrier stack 100 can alternatively be deposited directly on the device 160, e.g., an organic light emitting device, as depicted in FIG. 2 with respect to the embodiments excluding the fourth layer.

In some embodiments of the present invention, a method of making a barrier stack includes providing a substrate 150, which may be a separate substrate support or may be a device 160 for encapsulation by the barrier stack 100 (e.g., an organic light emitting device or the like). The method further includes forming a first layer 110 on the substrate. The first layer 110 is as described above and acts as a decoupling/smoothing/planarization layer. As also discussed above, the first layer 110 may be deposited on the device 160 or substrate 150 by any suitable deposition technique, including, but not limited to, vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of he first layer include spin coating, ink jet printing, screen printing and spraying.

The method further includes depositing a second layer 120 on the surface of the first layer 110. The second layer 120 is as described above and acts as a protecting layer for shielding the first layer 110 and the underlying device from plasma damage caused by deposition of the third layer 130, and for substantially preventing or substantially reducing the propagation of surface defects to the third layer 130, described above and below. The deposition of the second layer 120 may depend on the material of the second layer, as discussed above. For example, when the material of the second layer is an inorganic material (e.g., an oxide), the layer may be deposited by DC sputtering, and when the material of the second layer is a polymeric material, the layer may be deposited by a wet coating method. These methods are described in more detail above. Also, any deposition technique may be used as long as the deposited layer has the appropriate refractive index/density and thickness, as described above.

The method further includes depositing a third layer 130 on the surface of the second layer 120. The third layer 130 is as described above and acts as the barrier layer of the barrier stack, serving to substantially prevent or substantially reduce the permeation of damaging gases, liquids and chemicals to the underlying device. The deposition of the third layer 130 may vary depending on the material used for the third layer. However, in general, any deposition technique and any deposition conditions can be used to deposit the third layer so long as the third layer is deposited in such a manner as to yield a different density and/or refractive index than the second layer 120. For example, the third layer 130 may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof. In some embodiments, however, the third layer 130 is deposited by AC sputtering. While any suitable conditions for deposition can be employed, some suitable conditions are described above.

In some embodiments, the method further includes depositing a fourth layer 140 between the substrate 150 (or the device 160 to be encapsulated) and the first layer 110. The fourth layer 140 is as described above and acts as a tie layer for improving adhesion between the substrate or device and the first layer 110 of the barrier stack 100. The fourth layer 140 may be deposited by any suitable technique, as discussed above. For example, as also discussed above, the fourth layer 140 may be deposited on the substrate 150 (or the device 160 to be encapsulated) by any suitable technique. In some embodiments, for example, the fourth layer 140 is deposited by AC sputtering, as discussed above.

The following Examples are provided for illustrative purposes only, and do not limit the present disclosure. In the Examples, ATR-FTIR spectra were taken, and each of the spectra are normalized to the CHₓ stretch peaks in the region 2800-3000 cm⁻¹. Each of the Examples has a substrate/fourth layer/first layer/oxide layer(s) structure in which the substrate is glass, the fourth layer is an AC deposited oxide with a thickness of 40 nm, and the first layer is a polymer layer including a blend of lauryl acrylate, 1,12-dodecanediol dimethacrylate, trimethylpropane triacrylate, and Darocur TPO (a photoinitiator). The oxide layer in the structure was varied in the Examples, as described below.

### EXAMPLE 1

A barrier stack was prepared as discussed above, and the oxide layer included a pulsed DC sputtered aluminum oxide layer. The DC sputtering conditions included 2 passes at a power of 3.2 kW, a pressure of 2.5 mTorr, an Argon flow rate of 65 sccm, a target voltage of 290 V, and a 64 cm/min track speed. The deposited layer had a thickness of 40 nm.

EXAMPLE 2

A barrier stack was prepared as discussed above, and the oxide layer included an AC sputtered aluminum oxide layer. The AC sputtering conditions included 2 passes at a power of 4 kW, a pressure of 4.4 mTorr, an Argon flow rate of 100 sccm, a target voltage of 480V, and a 141 cm/min track speed. The deposited layer had a thickness of 40 nm.

### EXAMPLE 3

A barrier stack was prepared as discussed above, and the oxide layer included a second layer of a pulsed DC sputtered aluminum, oxide, and a third layer of an AC sputtered aluminum oxide. The pulsed DC sputtering conditions included 1 pass at a power of 3.2 kW, a pressure of 2.5 mTorr, an Argon flow rate of 65 sccm, a target voltage of 290 V, and a 64 cm/min track speed. The pulsed DC deposited layer had a thickness of about 20 nm. The AC sputtering conditions included 2 passes at a power of 4 kW, a pressure of 4.4 mTorr, an Argon flow rate of 100 sccm, a target voltage of 480 V, and a 141 cm/min track speed. The AC deposited layer had a thickness of 40 nm.

### EXAMPLE 4

A barrier stack was prepared as in Example 1, except that the track speed was 68 cm/min instead of 64 cm/min.

### EXAMPLE 5

A barrier stack was prepared as in Example 3, except that the track speed of the pulsed DC sputtering was 68 cm/min instead of 64 cm/min.

### EXAMPLE 6

A barrier stack was prepared as in Example 5, except that the thickness of the pulsed DC sputtered layer was about 30 nm instead of about 20 nm.

To determine the effectiveness of the various oxide layers in preventing or reducing damage to the underlying polymer layer, the amount of CO₂ is detected. Specifically, plasma damage to the polymer occurs by breakage of the acrylate bonds, which forms CO₂. The more damage the plasma causes, the more CO₂ is formed. By detecting the amount of CO₂ in the barrier stack after deposition of the top layer oxide, the amount of damage to the underlying polymer layer can be assessed. The CO₂ is detectable because the deposition of the top layer oxide creates a good barrier against the permeation of the CO₂. As such, once the top layer oxide is deposited, the CO₂ generated from the plasma deposition cannot escape through the top layer oxide barrier, and therefore remains trapped in the stack. The detected amount of CO₂ (i.e., the intensity of the CO₂ peak was the highest) in Example 2 (the AC sputtered top oxide layer) was more than in any of the other Examples. The intensity of the CO₂ peak produced by Example 3 (dual pulsed DC/AC oxide layers) was reduced compared to Example 2 (AC oxide layer), but increased compared to Example 1 (pulsed DC oxide). This suggests that the 20 nm thickness of the pulsed DC oxide layer was not enough to adequately protect the polymer layer from the heavier damage produced by AC sputtering. However, the intensities of the CO₂ peaks of Examples 5 and 6 (0 and 30 nm pulsed DC thickness, respectively, with 68 cm/min track speed) were similar to the peaks of Example 1 (pulsed DC oxide) but still reduced compared to Example 2 (AC oxide). The data confirms that the pulsed DC/AC oxide layer protects the polymer layer better than an AC sputtered oxide layer. The discrepancy in the data comparing Example 3 (pulsed DC/AC layer deposited at 64 cm/min track speed) to Example 1 (pulsed DC oxide layer), and the data comparing Example 4 (pulsed DC/AC oxide deposited at 68 cm/min) to Example 1, suggests that either the thickness of the pulsed DC oxide layer of Example 1 is actually greater than the measured value, or the longer exposure to plasma in Example 1 (due to the lower track speed) caused greater damage.

While certain exemplary embodiments of the present invention have been illustrated and described, it is understood by those of ordinary skill in the art that certain modifications and changes can be made to the described embodiments without departing from the spirit and scope of the present invention.

What is claimed is:

1. A barrier, comprising:
a first layer comprising a polymer or organic material;
a second layer on the first layer and comprising a plasma resistant material;
a third layer on the second layer and comprising an inorganic material, the third layer having a density and/or refractive index different from a density and/or refractive index of the second layer.

2. The barrier stack of claim 1, further comprising a fourth layer, wherein the first layer is on the fourth layer.

3. The barrier stack of claim 1, wherein the polymer or organic material is selected from the group consisting of organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

4. The barrier stack of claim 1, wherein the inorganic material of the third layer is selected from the group consisting of metals, metal oxides, metal nitrides, metal oxynitrides, metal carbides, metal oxyborides, Al, Zr, Ti, and combinations thereof.

5. The barrier stack of claim 1, wherein the plasma resistant material of the second layer is selected from the group consisting of plasma resistant polymers, metals, metal oxides, metal nitrides, metal oxynitrides, metal carbides, metal oxyborides, Al, Zr, Ti, and combinations thereof.

6. The barrier stack of claim 5, wherein the plasma resistant polymer is selected from the group consisting of silicone-based polymers, carbon-based polymers, silicones, polybutadienes, styrene butadienes, and combinations thereof.

7. The barrier stack of claim 1, wherein the second layer has a refractive index of greater than about 1.6 or lower than about 1.5, and a thickness of about 20 nm to about 100 nm.

8. The barrier stack of claim 1, wherein the third layer has a refractive index of about 1.6 or greater, and a thickness of about 20 nm to about 100 nm.

9. The barrier stack of claim 2, wherein the fourth layer has a thickness of about 20 nm to about 60 nm.

10. A method of making a barrier stack, comprising:
forming a second layer comprising a plasma resistant material over a first layer comprising a polymer or organic material;
forming a third layer comprising an inorganic material over the second layer;
wherein the third layer has a density and/or refractive index different from a density and/or refractive index of the second layer.

11. The method of claim 10, further comprising forming the first layer on a fourth layer.

12. The method of claim 10, wherein the polymer or inorganic material of the first layer comprises a material selected from the group consisting of organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

13. The method of claim 10, wherein the inorganic material of the third layer is selected from the group consisting of metals, metal oxides, metal nitrides, metal oxynitrides, metal carbides, metal oxyborides, Al, Zr, Ti, and combinations thereof.

14. The method of claim 10, wherein the plasma resistant material of the second layer comprises a material selected from the group consisting of plasma resistant polymers, metals, metal oxides, metal nitrides, metal oxynitrides, metal carbides, metal oxyborides, Al, Zr, Ti, and combinations thereof.

15. The method of claim 14, wherein the plasma resistant material is selected from the group consisting of silicone-based polymers, carbon-based polymers, silicones, polybutadienes, styrene butadienes, and combinations thereof.

16. The method of claim 10, wherein the second layer has a refractive index of greater than about 1.6 or lower than about 1.5, and a thickness of about 20 nm to about 100 nm.

17. The method of claim 10, wherein the third layer has a refractive index of about 1.6 or greater, and a thickness of about 20 nm to about 100 nm.

18. The method of claim 11, wherein the fourth layer has a thickness of about 20 nm to about 60 nm.

19. The method of claim 10, wherein the second layer is an inorganic material, the forming the second layer on the first layer comprises pulsed DC sputtering, and the forming the third layer on the second layer comprises AC sputtering.
